(19) United States
(12) Patent Application Publication
(10) Pub. No.: US 2026/0333966 A1
(43) Pub. Date: Oct. 22, 2026

(54) OPTICAL ARRANGEMENT AND METHOD FOR OPERATING AN OPTICAL ARRANGEMENT

(71) Applicant: ams-OSRAM International GmbH, Regensburg (DE)

(72) Inventors: Daniel DIETZE, Regensburg (DE); Wolfgang SCHMID, Kelheim (DE); Matthias GOLDBACH, Pentling (DE)

(21) Appl. No.: 19/115,759

(22) PCT Filed: Sep. 23, 2023
(86) PCT No.: PCT/EP2023/076332

§ 371 Date: Mar. 26, 2025

(30) Foreign Application Priority Data
Sep. 28, 2022 (DE) 10 2022 124 967.0

(51) Int. Cl. H10H 29/24; H05B 45/22; H05B 45/46; H05B 45/58

(52) U.S. Cl. CPC H10H 29/24; H05B 45/22; H05B 45/46; H05B 45/58

(57) ABSTRACT

An optical arrangement includes a first number N of light-emitting diodes (LEDs), a supply circuit, and a package. The supply circuit is configured to set a first light-emitting diode (LED) of the first number N of LEDs in a light-emitting state or an idle state and to set a LED of the first number N of LEDs in a light sensing state. The first number N of LEDs and the supply circuit are integrated in the package. The package has a cavity and the first number N of LEDs are inside the cavity. The cavity is filled with a transparent material or covered by a transparent sheet. A ray of light emitted by the first LED is reflected by an interface to the ambient and is directed towards the second LED. The interface is realized as an interface between the ambient and the transparent material or by the transparent sheet.

This patent application claims the priority of DE patent application 10 2022 124 967.0, the disclosure content of which is hereby incorporated by reference.

An optical arrangement and a method for operating an optical arrangement are provided.

An optical arrangement comprises two or more light-emitting diodes, abbreviated LEDs. The LEDs can be realized as multicolor LEDs. A degradation of the different LEDs can be different. Thus, a parameter which is used for characterizing a light source such as brightness, luminous intensity value, illuminance, chromaticity, correlated color temperature or tristimulus values may see a drift during lifetime of the optical arrangement.

It is an object to provide an optical arrangement and a method for operating an optical arrangement with a monitoring of emitted light.

The object is achieved by the subject-matter of the independent claims. Further developments are described in the dependent claims.

In an embodiment, an optical arrangement comprises a first number N of light-emitting diodes and a supply circuit. The first number N is larger than 1. The supply circuit is configured to set a first light-emitting diode of the first number N of light-emitting diodes in a light-emitting state or an idle state and to set a second light-emitting diode of the first number N of light-emitting diodes in a light sensing state.

Advantageously, the second light-emitting diode, abbreviated second LED, is configured to detect light emitted by the first light-emitting diode, abbreviated first LED.

Thus, the first LED can be monitored by the second LED. The monitoring allows to electrically adjust one of the first and the second LED, e.g. by increasing or decreasing a current, an averaged current and/or a duty cycle of a pulse-width modulated current that flows through the one of the first and the second LED.

In an alternative embodiment of the optical arrangement, the first number is 2 or 3 or 4 or at least 3 or at least 4.

In an embodiment of the optical arrangement, the first LED is configured to emit light at a first wavelength. The second LED is configured to emit light at a second wavelength. The first wavelength is equal or shorter than the second wavelength. Thus, the second LED is configured to detect light emitted by the first LED.

In an embodiment of the optical arrangement, the first LED is configured to emit light in a first emission spectrum. The second LED is configured to detect light in a sensitivity spectrum. The first emission spectrum of the first LED has an overlap with the sensitivity spectrum of the second LED. Due to the overlap, the second LED is configured to detect light emitted by the first LED.

In an example, the first wavelength is e.g. a peak wavelength of the first emission spectrum emitted by the first LED. Similarly, the second wavelength is e.g. a peak wavelength of a second emission spectrum emitted by the second LED.

In an embodiment of the optical arrangement, the first and the second emission spectrum are identical or nearly identical. Thus, the first and the second LED are both implemented as white LEDs, red LEDs, green LEDs or blue LEDs.

In an alternative embodiment of the optical arrangement, the first and the second emission spectrum are different.

Thus, for example, one of the first and the second LED is implemented as white LED, red LED, green LED or blue LED and the other of the first and the second LED is implemented as another one of the white LED, red LED, green LED or blue LED. The selection is performed such that there is an overlap of the first emission spectrum of the first LED and the sensitivity spectrum of the second LED, as described above.

In an embodiment of the optical arrangement, the first number N of LEDs comprises a third LED. The first number N is larger than 2. The supply circuit is configured to set the first and the second LED in the light-emitting state or in the idle state and to set the third LED in the light sensing state. Advantageously, the third LED is configured to detect light emitted by the second LED or light emitted by the first and the second LED. Therefore, depending on a sensitivity spectrum of the third LED and the first and the second emission spectra, the third LED is able to detect light emitted by the second LED only or by the first and the second LED. The first and the second LED are set in a light-emitting state during different periods (and not simultaneously). Thus, the second LED is monitored by the third LED and, optionally, also the first LED is monitored by the third LED (in a different period or another point of time).

In an embodiment of the optical arrangement, the first LED is a blue LED, the second LED is a green LED and the third LED is a red LED.

In an alternative embodiment of the optical arrangement, the first LED is a blue LED, the second LED is a green LED and the third LED is a yellow LED.

In an alternative embodiment of the optical arrangement, the first number is four. For example, the first LED is a blue LED, the second LED is a green LED, the third LED is a yellow LED and a fourth LED is a red LED.

In an embodiment of the optical arrangement, the second LED is configured to emit light at a second wavelength. The third LED is configured to emit light at a third wavelength. The second wavelength is equal or shorter than the third wavelength.

In an embodiment of the optical arrangement, the second LED is configured to emit light in the second emission spectrum. The third LED is configured to detect light in a further sensitivity spectrum. The second emission spectrum of the second LED has an overlap with the further sensitivity spectrum of the third LED. The third LED has a third emission spectrum.

In an embodiment of the optical arrangement, the third LED is configured to detect light emitted by the second LED and the second LED is configured to detect light emitted by the first LED.

In an embodiment of the optical arrangement, the first, second and third emission spectra are identical or nearly identical. Thus, the first, second and third LED are implemented as white LEDs, red LEDs, green LEDs or blue LEDs.

In an alternative embodiment of the optical arrangement, the first, the second and the third emission spectrum are different. Thus, the first LED is implemented as white LED, red LED, green LED or blue LED, the second LED is implemented as another one of the white LED, red LED, green LED or blue LED and the third LED is implemented as a further one of the white LED, red LED, green LED or blue LED. The selection is performed such that
there is an overlap of the first emission spectrum of the first LED and the sensitivity spectrum of the second LED or the further sensitivity spectrum of the third LED and
there is an overlap of the second emission spectrum of the second LED and the further sensitivity spectrum of the third LED.

In an embodiment of the optical arrangement, in a first measuring phase, the supply circuit is configured to set the first LED in the light-emitting state, to set the second LED in the light sensing state and to measure a first light signal provided or detected by the second LED. The first light signal is generated by means of the second LED. The supply circuit measures the first light signal. For example, the supply circuit digitizes the first light signal and generates a first digitized light signal as a function of the first light signal.

In an embodiment of the optical arrangement, in a first background measuring phase, the supply circuit is configured to set the first LED in an idle state, to set the second LED in the light sensing state and to measure a first background light signal detected by the second LED. In an example, the first background measuring phase is before the measuring phase or is after the measuring phase. In an alternative example, the first background measuring phase is before the measuring phase and a second background measuring phase is after the measuring phase. The operations during the first and the second background measuring phases are e.g. identical.

In an embodiment of the optical arrangement, in a regular phase, the supply circuit is configured to set the first and the second LED in the light-emitting state; a parameter of operation of the first and/or the second LED is adjusted as a function of the first light signal. In an example, the regular phase is after the measuring phase.

In an embodiment of the optical arrangement, the supply circuit comprises a control circuit, a memory and an analog-to-digital converter. The analog-to-digital converter is configured to digitize the first light signal or a signal that depends on the first light signal into a first digitized light signal. The control circuit is configured to store the first digitized light signal or a parameter derived from the first digitized light signal in the memory. These steps are performed in the measuring phase and in the background measuring phase. The control circuit is configured to determine an adjustment parameter as a function of the first digitized light signal detected in the measuring phase and in the background measuring phase and to control one of the first number of LEDs in the following regular phase as a function of the adjustment parameter.

In an embodiment of the optical arrangement, the supply circuit is configured to operate with pulse-width modulation. A first duty cycle of the first LED and/or a second duty cycle of the second LED is adjusted as a function of the first light signal or the first digitized light signal or of the adjustment parameter.

In an embodiment of the optical arrangement, the supply circuit comprises a first driver stage coupled to the first LED and to the control circuit. The supply circuit comprises a driver and measuring stage coupled to the second LED and to the control circuit. For example, the first driver stage is switched on and off during the regular phase, the measurement phase and the background measurement phase as a function of the first duty cycle.

In an embodiment of the optical arrangement, the driver and measuring stage comprises a second driver stage and a measuring stage. The second driver stage or the measuring stage are alternatively coupled to the second LED. For example, the second driver stage is switched on and off during the regular phase as a function of the second duty cycle and is continuously switched off during the measurement phase and the background measurement phase. The measuring stage operates during the measurement phase and the background measurement phase.

For example, in case the third LED monitors the second LED, the second driver stage is switched on and off during a further measurement phase and a further background measurement phase as a function of the second duty cycle.

In an embodiment of the optical arrangement, the driver and measuring stage comprises a change-over switch which is coupled on one side to the second LED and on another side to the second driver stage (e.g. during the regular phase of operation) and the measuring stage (e.g. during the measurement phase and the background measurement phase).

In an embodiment of the optical arrangement, the measuring stage comprises a transimpedance amplifier with a first input coupled or connected to the second LED.

In an embodiment of the optical arrangement, the second LED has a first terminal coupled to a supply terminal and a second terminal coupled to the first input of the transimpedance amplifier. A second input of the transimpedance amplifier is coupled or connected to the supply terminal.

In an embodiment, the optical arrangement further comprises a package. The package can also be named housing, enclosure or LED package. The first number N of light-emitting diodes and the supply circuit are integrated in the package. Thus, the first driver stage and the driver and measuring stage with the second driver stage and the measuring stage are integrated in the package. In an example, a distance of the first and the second LED is less than a predetermined value. The housing comprises an interface at which light emitted by the first LED is partially reflected such that a reflected light is at least partially absorbed by the second LED. A distance of the first LED to the interface is larger than a predetermined height value.

In an embodiment, a method for operating an optical arrangement comprises
controlling a first LED of a first number N of LEDs by a supply circuit such that the first LED emits light, and
controlling a second LED of the first number N of LEDs by the supply circuit such that the second LED senses light.

The optical arrangement described above is particularly suitable for the method for operating an optical arrangement. Features described in connection with the optical arrangement can therefore be used for the method for operating an optical arrangement and vice versa.

In an example, the optical arrangement comprises multicolor LEDs with built-in degradation compensation. The optical arrangement relates to all multicolor LEDs where several LED chips (minimum 2) are placed in one common cavity. The optical arrangement is realized for RGB LEDs with integrated driver IC, where excellent color stability is advantageous, and the IC is configured to provide test modes. Stable mixed colors in the whole accessible gamut without the need of external measurement equipment both for short-term and over lifetime is achieved. The stabilization is achieved despite degradation of single LEDs. There is no need for a burn-in of the LEDs at assembly (however, a burn-in is possible). To serve novel advanced ambient illumination and signaling applications, the optical arrangement is implemented as RGB illumination module that realizes tight integration of at least three LEDs and a dedicated driver IC into a single optical package with minimal size and height.

In addition, a LED manufacturer or a company assembling LED modules can provide optical calibration data (“0-h”) for each LED, either through package marking or stored in the supply circuit to simplify the integration effort at the customer site, leading to an advantage. The supply circuit is implemented in an integrated circuit.

In an example, given the large number of emitters employed e.g. in modern cars, color stability (both in terms of temperature stability and over time) of the LEDs becomes very important to offer an optimal color impression for the end customer. Active compensation of temperature and degradation induced color shifts is only possible via optical feedback. This is usually done with additional photodiodes, adding to the footprint, cost and complexity of the system.

In an example, the optical arrangement proposes a way to realize optical feedback for controlling temperature and aging induced color shifts in a multicolor LED package without additional components, especially without external components.

In an example, the first and the second LED have different spectra. The first, second and third LED have three different spectra.

Advantageously, the optical arrangement provides a fully integrated solution. The optical arrangement performs a direct online feedback of actual LED behavior, not just nominal. The optical arrangement relates to a multicolor LED possibly with integrated controller unit (IC) that uses the LEDs themselves as optical sensor to monitor the optical output power of their fellow LEDs in combination with an aging-stabilized red LED.

In an example, the LEDs are placed in one common cavity. In turn, one LED is used as photodetector to record the emission of another LED or other LEDs. The supply circuit features a readout circuit compatible with the LED arrangement (typically common anode). There is a nonvolatile memory to hold the reference and calibration data.

Advantageously, stable mixed colors in the whole accessible gamut are emitted by the optical arrangement without the need of external measurement equipment both for short-term and over lifetime. There is no need for a burn-in of the LEDs at assembly. Due to the online compensation, the inherent stability of the LEDs becomes less critical and aging requirements can be relaxed. The method works with both different chip suppliers. In an example, the optical arrangement realizes RGB LEDs with built-in driver IC.

The following description of figures of examples or embodiments may further illustrate and explain aspects of the optical arrangement and the method for operating an optical arrangement. Arrangements, devices, circuit blocks and layers with the same structure and the same effect, respectively, appear with equivalent reference symbols. In so far as arrangements, devices, circuit blocks and layers correspond to one another in terms of their function in different figures, the description thereof is not repeated for each of the following figures.

FIG. 1 shows an example of a LED and its characteristic;

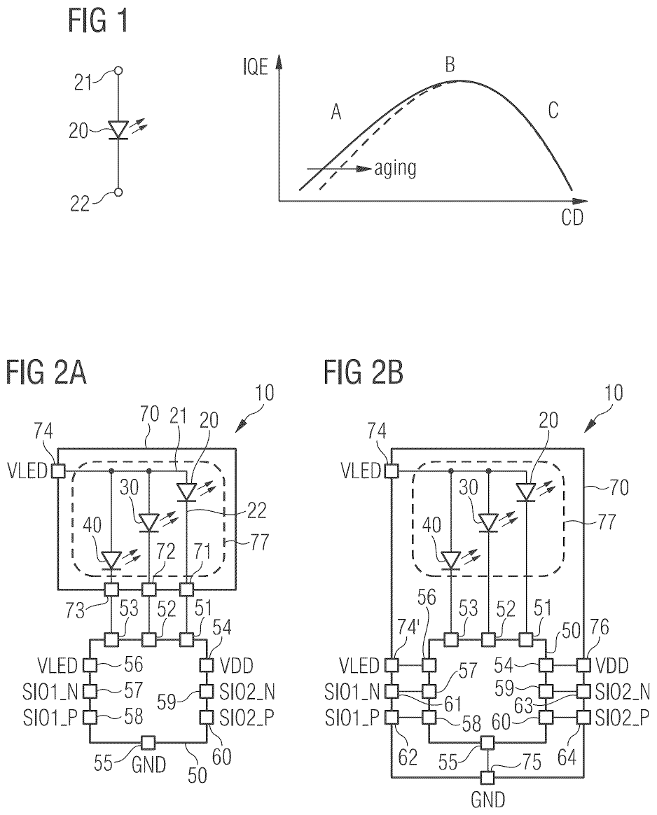

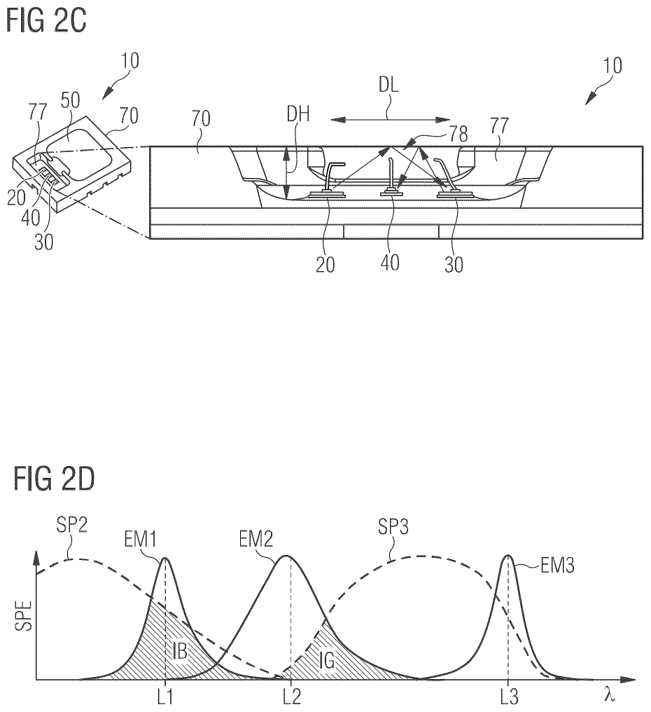

FIGS. 2A to 2D show exemplary embodiments of an optical arrangement;

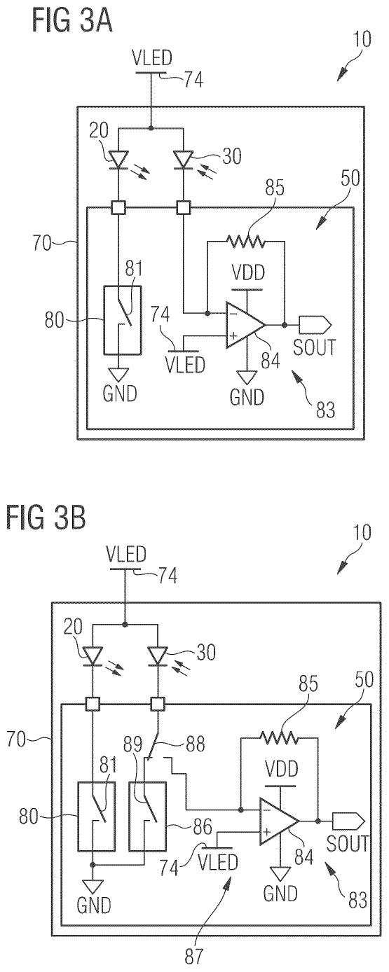

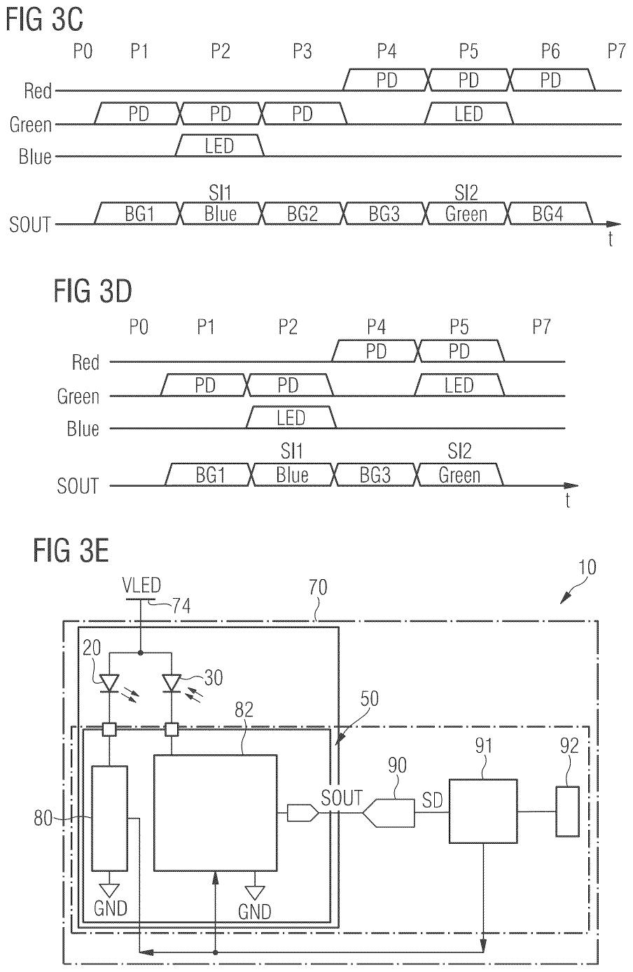

FIGS. 3A to 3E show further exemplary embodiments of an optical arrangement; and

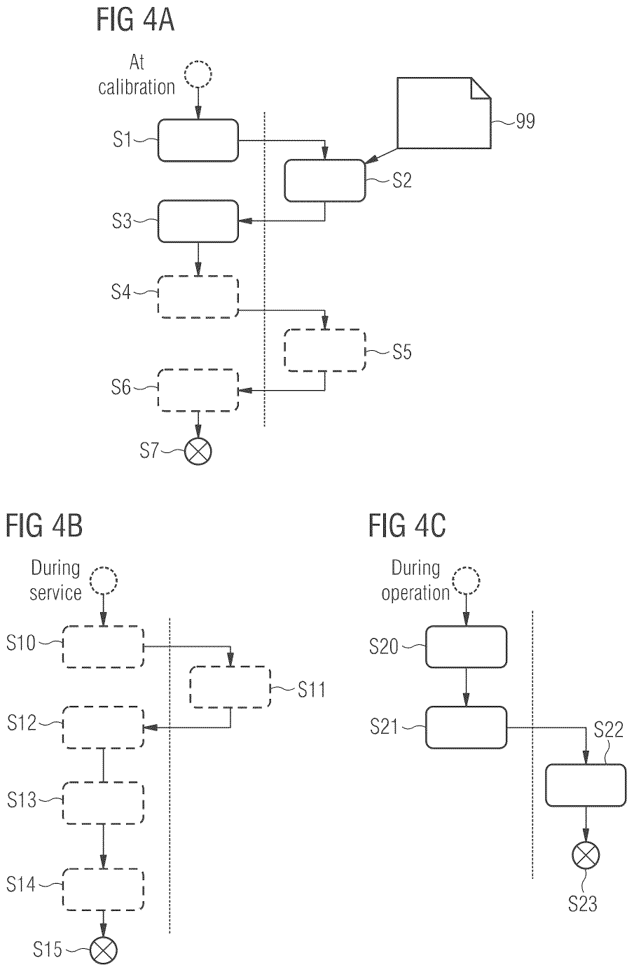

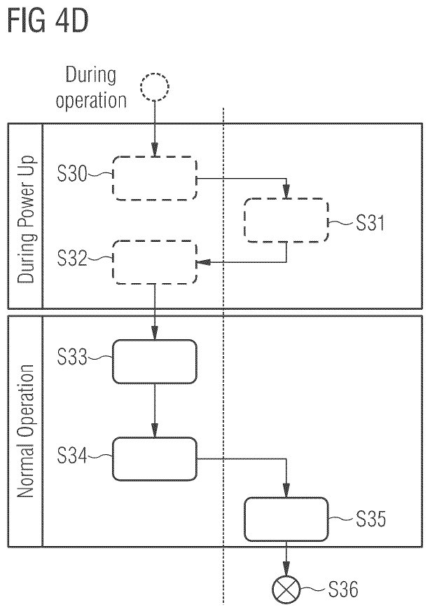

FIGS. 4A to 4D show exemplary embodiments of a method for operating an optical arrangement.

FIG. 1 shows an example of a light-emitting diode, such as a first light-emitting diode 20 and its characteristic. An internal quantum efficiency IQE is shown versus a current density CD of the first LED 20. LED operation takes place at medium current densities CD and covers all three loss channels: Shockley-Read-Hall (marked A, abbreviated SRH), radiative (marked B) and Auger (marked C). The non-radiative loss channels SRH and Auger reduce the portion of the current actually contributing to visible light emission. The SRH regime is dominated by defects and is the dominating contributor to LED aging. The first LED 20 has a first and a second terminal 21, 22. The first terminal 21 is e.g. an anode of the first LED 20. The second terminal 22 is e.g. a cathode of the first LED 20.

For a photodetector or a LED used as photodetector, defects cause an increase of dark current but do not reduce the generated current, i.e. sensitivity. Dark current is proportional to the applied reverse bias. Using a transimpedance amplifier setup, abbreviated TIA setup, as shown e.g. in FIGS. 3A to 3E, the photodetector is held at zero bias, effectively removing the dark current.

FIG. 2A shows an exemplary embodiment of an optical arrangement 10. The optical arrangement 10 comprises a first number N of LEDs 20, 30, 40 and a supply circuit 50. The supply circuit 50 is configured to set a first LED 20 of the first number N of LEDs 20, 30, 40 in a light-emitting state or an idle state. The supply circuit 50 is configured to set a second LED 30 of the first number N of LEDs 20, 30, 40 in a light sensing state, a light-emitting state or an idle state. At different points of time, the first LED 20 is set in the light-emitting state and the idle state. At different points of time, the second LED 30 is set in the light sensing state, the light-emitting state and the idle state. The supply circuit 50 is realized e.g. as a single integrated circuit. The supply circuit 50 can be named as driver integrated circuit, abbreviated driver IC or controller. A LED in the idle state does not receive current. A LED in the idle state does not emit light.

The first number N of LEDs 20, 30, 40 comprises a third LED 40. The first number N is e.g. larger than 1 or than 2 or than 3. The supply circuit 50 is configured to set the third LED 40 in a light sensing state, a light-emitting state or an idle state. At different points of time, the third LED 40 is set in the light sensing state, the light-emitting state and the idle state.

The optical arrangement 10 comprises a package 70. The first number N of LEDs 20, 30, 40 is integrated in the package 70. The supply circuit 50 is not part of the package 70. The package 70 has a cavity 77. The first number N of LEDs 20, 30, 40 are attached inside the cavity 77.

The optical arrangement 10 comprises a LED supply terminal 74 and a reference potential terminal 55. The LED supply terminal 74 is coupled via a series circuit to the reference potential terminal 55. The series circuit comprises or is formed by the first number N of LEDs 20, 30, 40 and the supply circuit 50.

The LED supply terminal 74 is coupled via the first number N of LEDs 20, 30, 40 to the supply circuit 50. The supply circuit 50 is connected or coupled to the reference potential terminal 55. The supply circuit 50 comprises a first number N of terminals 51 to 53 which are coupled or connected to the first number N of LEDs 20, 30, 40. Thus, one terminal is connected to one LED. Second terminals 22 of the first number N of LEDs 20, 30, 40 are connected or coupled to the first number N of terminals 51 to 53 of the supply circuit 50. First terminals 21 of the first number N of LEDs 20, 30, 40 are connected or coupled to the LED supply terminal 74. A LED supply voltage VLED is provided at the LED supply terminal 74. A reference potential or ground potential GND is tapped at the reference potential terminal 55. The LED supply voltage VLED is e.g. positive with respect to the reference potential GND.

The optical arrangement 10 comprises a LED triplet mounted in one package 70 and the driver IC 50. Alternatively, the optical arrangement 10 comprises two LEDs or more than three LEDs (e.g. four LEDs, five LEDs etc.). The supply circuit 50 comprises a supply terminal 54 and at least an input terminal 57 to 60. The at least an input terminal 57 to 60 is a digital terminal. The at least an input terminal 57 to 60 is realized e.g. as input/output terminal. Optionally, the supply circuit 50 comprises a LED supply input 56. The LED supply voltage VLED is applied to the LED supply input 56.

In an example, the other contact of each LED 20, 30, 40 (e.g. cathode) is directly connected to the LED supply input 56 of the supply circuit 50. The LED supply input 56 is a dedicated pad on the integrated driver IC 50 or is made accessible to an external driver IC.

FIG. 2B shows an exemplary embodiment of an optical arrangement 10 which is a further development of the embodiment shown in FIG. 2A. The first number N of LEDs 20, 30, 40 and the supply circuit 50 are integrated in the package 70. Thus, a single package 70 comprises the first number N of LEDs 20, 30, 40 and the supply circuit 50. The first number N of LEDs 20, 30, 40 and the supply circuit 50 are not separated in different packages.

The package 70 has the following terminals: The LED supply terminal 74, a ground terminal 75 (connected to the reference potential terminal 55 of the supply circuit 50), at least one input terminal 61 to 64 (connected to the at least one input terminal 57 to 60 of the supply circuit 50) and optionally a IC supply terminal 76 (connected to the supply terminal 54 of the supply circuit 50). The package 70 may have a further LED supply terminal 74′ which is externally connected e.g. to the LED supply terminal 74.

FIG. 2C shows an exemplary embodiment of an optical arrangement 10 which is a further development of the embodiments shown in FIGS. 2A and 2B. An example for a product embodiment/a package embodiment is illustrated in FIG. 2C. On the left side, a three-dimensional view on the optical arrangement 10 is shown. The first number of LEDs 20, 30, 40 are located in the cavity 77 of the package 70. The first number of LEDs 20, 30, 40 are coupled to the supply circuit 50 e.g. via bonding wires.

On the right side, a cross-section of the optical arrangement 10 is elucidated. The cavity 77 is filled with a transparent material or is covered by a transparent sheet. A ray of light emitted by the first LED 20 is reflected by an interface 78 to the ambient and is directed towards the second LED 30. A ray of light emitted by the second LED 30 is reflected by the interface 78 to the ambient and is directed towards the third LED 40. The interface 78 is realized as an interface between the ambient and the transparent material or by the transparent sheet. Most of the light emitted by the first number of LEDs 20, 30, 40 reaches the ambient and only a small portion of this light is reflected by the interface 78.

A distance of the first LED 20 to the second LED 30 is less than a predetermined value DL. A distance of the second LED 30 to the third LED 40 is less than the predetermined value DL. The predetermined value DL is e.g. in a range between 100 μm and 200 μm or between 120 μm and 180 μm. A typical value for the predetermined value DL is 150 μm. A distance of the first LED 20 to the interface 78 is larger than a predetermined height value DH. A distance of the second LED 30 to the interface 78 is larger than the predetermined height value DH. A distance of the third LED 40 to the interface 78 is larger than the predetermined height value DH. The predetermined height value DH is e.g. in a range between 20 μm and 500 μm or between 30 μm and 400 μm or between 40 μm and 300 μm or between 50 μm and 200 μm. Thus, a ray of light emitted by the first LED 20 is detected by the second LED 30. A ray of light emitted by the second LED 30 is detected by the third LED 40.

FIG. 2D shows an exemplary embodiment of spectra of an optical arrangement 10 which is a further development of the embodiments shown in FIGS. 1 and 2A to 2C. Different spectra SPE are shown as a function of a wavelength λ. The first LED 20 emits light in a first emission spectrum EM1. A first wavelength L1 is a peak wavelength of the first emission spectrum EM1.

The second LED 30 emits light in a second emission spectrum EM2 and detects light in a sensitivity spectrum SP2. A second wavelength L2 is a peak wavelength of the second emission spectrum EM2. The second emission spectrum EM2 and the sensitivity spectrum SP2 are not equal. The sensitivity spectrum SP2 is shifted towards smaller wavelengths λ in comparison to the second emission spectrum EM2.

The third LED 40 emits light in a third emission spectrum EM3 and detects light in a further sensitivity spectrum SP3. A third wavelength L3 is a peak wavelength of the third emission spectrum EM3. The third emission spectrum EM3 and the further sensitivity spectrum SP3 are not equal. The further sensitivity spectrum SP3 is shifted towards smaller wavelengths λ in comparison to the third emission spectrum EM3.

The first wavelength L1 is shorter than the second wavelength L2. The first emission spectrum EM1 of the first LED 20 has an overlap IB with the sensitivity spectrum SP2 of the second LED 30.

The second wavelength L2 is shorter than the third wavelength L3. The second emission spectrum EM2 of the second LED 30 has an overlap IG with the further sensitivity spectrum SP3 of the third LED 40.

As the LEDs 20, 30, 40 are only sensitive to light with shorter to equal wavelengths compared to their emission spectrum, each LED 30, 40 monitors the optical output power of the LED 20, 30 with the next shorter wavelength. For example, the first LED 20 is a blue LED and the second LED 30 is a green LED. The first LED 20 is monitored using the second LED 30 as detector. The third LED 40 is e.g. a red LED. The second LED 30 is monitored using the third LED 40 as detector.

The readout of a photocurrent provided by one of the LEDs 30, 40 is realized through an integrated IC or via external circuitry. This signal is then used to compensate any aging induced color shifts of the monitored LEDs.

The LED with the longest wavelength (in FIG. 2D the first LED 20) cannot be stabilized by this method and acts as reference.

As both the brightness of a LED and the sensitivity of the LED when used as photodetector show a distinct dependency over temperature, the reference measurement is advantageously done under identical conditions (e.g. at service intervals). Alternatively, the temperature dependency can be reduced by measuring a temperature with a temperature sensor, e.g. to provide both degradation and temperature compensation. The temperature sensor (not shown) is comprised by the supply circuit 50.

The emitters have a set of different emission wavelengths, e.g. red, green and blue and are mounted on separate pads or on a common pad (e.g. common anode pad). The emission spectrum EM1, EM2, EM3 of each but the last LED 20, 30 has an overlap with the sensitivity spectrum SP2, SP3 of at least one other LED 30, 40; the overlap areas are marked with IB and IG in FIG. 2D.

The optical arrangement 10 achieves at least one of the following advantages, such as e.g.: Stable mixed colors are emitted in the whole accessible gamut without the need of external measurement equipment both for short-term and over lifetime. There is no need for a burn-in of the LEDs at assembly (but a burn-in is possible). Due to the online compensation, the inherent stability of the LEDs 20, 30, 40 becomes less critical and aging requirements can be relaxed. The method works with LEDs from different chip suppliers.

FIG. 3A shows an exemplary embodiment of an optical arrangement 10 which is a further development of the embodiments shown in FIGS. 2A to 2D. The supply circuit 50 comprises a first driver stage 80 coupled to the first LED 20 and to a control circuit 91 (shown in FIG. 3E). The first driver stage 80 includes a switch 81. The supply circuit 50 comprises a driver and measuring stage 82 coupled to the second LED 30 and to the control circuit 91. The driver and measuring stage 82 comprises a second driver stage 86 and a measuring stage 87. The second driver stage 86 and the measuring stage 87 are coupled to the second LED 30 alternatively (that means in different periods and not simultaneously).

The measuring stage 87 comprises a transimpedance amplifier 83 (abbreviated TIA) with a first input coupled to the second LED 30. The second LED 30 has a first terminal coupled to the LED supply terminal 74 and a second terminal coupled to the first input of the TIA 83. A second input of the TIA 83 is coupled or connected to the supply terminal 74. The TIA 83 comprises an operational amplifier 84 and a resistor 85 which couples an output of the operational amplifier 84 to a first input of the operational amplifier 84. The first input of the operational amplifier 84 forms the first input of the TIA 83. A second input of the operational amplifier 84 forms the second input of the TIA 83. The output of the operational amplifier 84 forms the output of the TIA 83.

There are many possible ways to readout the photocurrent from a photodiode or a LED used as photodiode. FIG. 3A shows a configuration that is compatible with the typical situation in multicolor LED packages 70: The LEDs 20, 30, 40 are typically connected directly to the positive LED supply voltage VLED and the supply circuit 50 is using low side switches 81, 89 to drive the LEDs 20, 30, 40.

Using the TIA 83 in this manner also allows to maintain a 0 V bias across the second LED 30 acting as a photodiode, thereby, effectively eliminating dark current. An output voltage or output signal SOUT of the TIA 83 is proportional to the photocurrent coming from the second LED 30, but generated using photons emitted by the first LED 20.

FIG. 3B shows an exemplary embodiment of an optical arrangement 10 which is a further development of the embodiments shown in FIGS. 2A to 2D and 3A. The driver and measuring stage 82 comprises a change-over switch 88 which is coupled on one side to the second LED 30 and on another side to the second driver stage 86 and to the measuring stage 87. The change-over switch 88 is controlled by the control circuit 91. The second driver stage 86 comprises a switch 89.

FIG. 3C shows an exemplary embodiment of timing signals of an optical arrangement 10 which is a further development of the embodiments shown in FIGS. 2A to 2D, 3A and 3B. In an example, eight phases P0 to P7 are shown as a function of a time t. In a prephase P0, the optical arrangement 10 is idle. The eight phases P0 to P7 follow one after another according to their numbers.

In a first background measuring phase P1, the supply circuit 50 sets the first and the third LED 20, 40 in an idle state, sets the second LED 30 in a light sensing state and measures a first background light signal BG1 detected by the second LED 30 (e.g. by means of the TIA 83).

In a first measuring phase P2, the supply circuit 50 sets the first LED 20 in the light-emitting state, sets (or keeps) the third LED 40 in an idle state, sets the second LED 30 in the light sensing state and measure a first light signal SI1 detected by the second LED 30 as a function of light emitted by the first LED 20 (e.g. by means of the TIA 83). The phases P1 to P7 can be named phases of operation.

In a further first background measuring phase P3, the supply circuit 50 sets the first and the third LED 20, 40 in an idle state, sets the second LED 30 in a light sensing state and measures a further first background light signal BG2 detected by the second LED 30.

In a second background measuring phase P4, the supply circuit 50 sets the first and the second LED 20, 30 in an idle state, sets the third LED 40 in a light sensing state and measures a second background light signal BG3 detected by the third LED 40 (e.g. by means of a TIA 83).

In a second measuring phase P5, the supply circuit 50 sets the first LED 20 in an idle state, sets the second LED 30 in the light-emitting state, sets the third LED 40 in the light sensing state and measure a second light signal SI2 detected by the third LED 40 as a function of light emitted by the second LED 30 (e.g. by means of the TIA 83).

In a further second background measuring phase P6, the supply circuit 50 sets the first and the second LED 20, 30 in an idle state, sets the third LED 40 in a light sensing state and measures a further second background light signal BG4 detected by the third LED 40 (e.g. by means of a TIA 83).

After the further second background measuring phase P6, a regular phase of operation P7 starts. In the regular phase of operation P7, the supply circuit 50 sets the first, second and third LED 20, 30, 40 in the light-emitting state, e.g. continuously or using pulse-width modulated control signals with a first, second and third duty cycle D1 to D3. At least a parameter of operation of the first, the second and/or the third LED 20, 30, 40 is adjusted as a function of the first light signal SI1, the second light signal SI2, the first background light signal BG1, the further first background light signal BG2, the second background light signal BG3 and the further second background light signal BG4.

These signals SI1, SI2, BG1, BG2, BG3 and BG4 are e.g. values of the output signal SOUT of the TIA 83 or values of a digitized output signal SD provided by an analog-to digital converter 90 shown in FIG. 3E.

In order to measure the current brightness of the blue and green LEDs 20, 30, for example one of the two timing sequences shown in FIG. 3C and FIG. 3D (explained below) are used. One of the LEDs is used as photodiode to measure both the background signal BG1, BG3 and the first light signal SI1 with background and emission of another LED. This procedure is then repeated with the next LED pair and so on.

A brightness IB of the first LED 20 is then obtained as:

IB=SI1−0.5 (BG1+BG2)

A brightness IG of the second LED 30 is then obtained as:

IG=SI2−0.5 (BG3+BG4)
using the nomenclature from FIG. 3C.

FIG. 3D shows an exemplary embodiment of timing signals of an optical arrangement 10 which is a further development of the embodiments shown in FIGS. 2A to 2D and 3A to 3C. In an example, six phases P0 to P2, P4, P5 and P7 are shown as a function of the time t. The further first background measuring phase P3 and the further second background measuring phase P6 are omitted.

The regular phase P7 starts after the measuring phase P1 to P6. The optical arrangement 10 relates to a multicolor LED possibly with integrated controller unit that uses the LEDs 30, 40 themselves as optical sensor to monitor the optical output power of their fellow LEDs 20, 30, e.g. in combination with an aging-stabilized red LED 40.

The brightness IB of the first LED 20 is obtained as:

IB=SI1−BG1

The brightness IG of the second LED 30 is obtained as:

IG=SI2−BG3
using the nomenclature from FIGS. 3C and 3D.

FIG. 3E shows an exemplary embodiment of an optical arrangement 10 which is a further development of the embodiments shown in FIGS. 2A to 2D and 3A to 3C. The supply circuit 50 comprises the analog-to-digital converter 90 (abbreviated ADC), the control circuit 91 and a memory 92. Therein, the ADC 90 digitizes the output signal SOUT of the TIA 83 such as e.g. the first and the second light signal SI1, SI2 or a signal that depends on the first and the second light signal SI1, SI2 into a first and a second digitized light signal SD1, SD2. The control circuit 91 stores the first and the second digitized light signal SD1, SD2 or a parameter depending on the first and the second digitized light signal SD1, SD2 in the memory 92. The output voltage SOUT of the TIA 83 is digitized into the digitized output signal SD, for example, using a standard ADC 90. The memory 92 is e.g. nonvolatile or volatile. The memory 92 is coupled to the control circuit 91.

The supply circuit 50 operates with pulse-width modulation. A first duty cycle D1 of the first LED 20 and/or a second duty cycle D2 of the second LED 30 and/or a third duty cycle D3 of the third LED 40 is adjusted as a function of the first and the second light signal SI1, SI2 and of the first and the second background light signal BG1, BG3 (and optionally also of the further first and second background light signal BG2, BG4). For example, one of the three duty cycles D1, D2, D3 is kept constant and the other two of the three duty cycles D1, D2, D3 are adjusted as a function of the first and the second light signal SI1, SI2 and of the first and the second background light signal BG1, BG3 (and optionally also of the further first and second background light signal BG2, BG4).

FIG. 4A shows an exemplary embodiment of a method for operating an optical arrangement 10 which is a further development of the embodiments shown in FIGS. 2A to 2D and 3A to 3E. In FIG. 4A, a method for operating the optical arrangement 10 during calibration is shown.

On the left side of the dashed line shown in FIG. 4A, steps or processes performed by a microcontroller unit and on the right side of the dashed line steps or processes performed by the first number of LEDs 20, 30, 40 are shown (this is also the case at FIGS. 4B to 4D). The control circuit 91 or an external circuit comprises the microcontroller unit. Thus, the control circuit 91 comprises e.g. a microcontroller, a microprocessor, a state machine or logic gates.

During calibration, the following steps or processes are preformed:
Process S1: The calibration is started by the microcontroller unit.
Process S2: Calibration values such as e.g. chromaticity values Cx, Cy and an intensity value Iv are determined using an external measurement equipment 99 (e.g. a spectrometer).
Process S3: The calibration values such as e.g. the chromaticity values Cx, Cy and the intensity value Iv are stored.
Process S4: Initial brightness values are recorded.
Process S5: The monitoring process is performed such as described above e.g. in FIGS. 3A to 3D.
Process S6: The initial brightness values IG0, IB0 are stored.
Process S7: End of calibration

Processes S1 to S3 are standard processes. Processes S4 to S6 are processes using the supply circuit 50 as described above.

The initial brightness values of the blue and green LEDs 20, 30 is measured at the very beginning and is stored in some kind of non-volatile memory either provided by/with the microcontroller that is used to control the LED or by the driver IC integrated in the LED. In the first case, the memory can be programmed multiple times. In the second case, the memory can very likely only be programmed once. In an example, the control circuit 91 stores the initial brightness values IGO, IBO in the memory 92.

FIGS. 4B and 4C shows an exemplary embodiment of a method for operating an optical arrangement 10 which is a further development of the embodiments shown in FIGS. 2A to 2D, 3A to 3E and 4A.

As shown in FIG. 4B, during service, the following steps or processes are performed:
Process S10: The current brightness values are recorded.
Process S11: The monitoring process as described above is performed.
Process S12: New intensity values Iv are calculated.
Process S13: Stored calibration values (e.g. intensity values Iv) are modified.
Process S14: Stored brightness values IB0, IG0 are modified.
Process S15: End

As shown in FIG. 4C, during operation, the following steps or processes are performed:
Process S20: PWM settings are calculated from stored calibration data (the PWM settings comprise e.g. the first. second and third duty cycle D1, D2, D3).
Process S21: The PWM settings are set.
Process S22: The PWM settings are applied to the first, second and third LED 20, 30, 40.
Process S23: Continue

Processes S10 to S15 are performed during service (FIG. 4B) and e.g. implement the optical arrangement 10 and the methods described above. Processes S20 to S23 are performed during operation (FIG. 4C) and e.g. are standard processes.

In FIGS. 4B and 4C, a first option for degradation compensation during lifetime is explained. Degradation correction is done only during service intervals, e.g. every few months. The new brightness readings are stored in the non-volatile memory 92 and the original calibration data e.g. intensity values Iv—is overwritten with the corrected value. Daily operation proceeds e.g. without degradation correction. The PWM values can be calculated based on the stored calibration data.

This method is compatible with a non-volatile memory 92 that supports multiple programming cycles, e.g. non-volatile memory realized as a flash.

Optionally, this measurement is done under identical conditions as the initial calibration, e.g. at the same ambient temperature. Alternatively, a temperature sensor can be used together with the distinct temperature dependency of a LED and of the LED used as photodetector to compensate differences between the calibration temperature and the temperature during the compensation measurement.

The modified intensity values IvB1, IvG1 are calculated as

IvB1=IvB0·IB1/IB0

and

IvG1=IvG0·IG1/IG0
wherein IvB1 is the intensity value of the first LED 20, IvG1 is the intensity value of the second LED 30,
IB1 is a measured brightness of the first LED 20,
IB0 is a measured brightness of the first LED 20 obtained during the calibration phase,
IvB0 is a measured intensity value of the first LED 20 obtained during the calibration phase,
IG1 is a measured brightness of the second LED 30,
IG0 is a measured brightness of the second LED 30 obtained during the calibration phase, and
IvG0 is a measured intensity value of the second LED 30 obtained during the calibration phase.

The intensity value IvG1 of the second LED 30 and the intensity value IvB1 of the first LED 20 are stored instead of the previous intensity values IvB0 and IvG0 or stored in addition to the previous intensity values IvB0 and IvG0. Intensity value IvXX refers to luminous intensity emitted by a LED 20, 30, 40 and brightness IXX refers to the measurement result from the photodetector (realized as LED). The intensity value and the brightness are related but have different units etc. Thus, the previous intensity values of IvG0 and IvB0 are overwritten by the new intensity values IvG1 and IvB1.

FIG. 4D shows an exemplary embodiment of a method for operating an optical arrangement 10 which is a further development of the embodiments shown in FIGS. 2A to 2D, 3A to 3E and 4A to 4C.

As shown in FIG. 4D, during operation, the following steps or processes are performed:
Process S30: The current brightness values are recorded.
Process S31: The monitoring process as described above is performed.
Process S32: New intensity values Iv are calculated.
Process S33: PWM settings are calculated from stored and temporary calibration data (the PWM settings comprise e.g. the first, second and third duty cycle D1, D2, D3).

Process S34: The PWM settings are set.

Process S35: The PWM settings are applied to the first, second and third LED 20, 30, 40 by the supply circuit 50.

Process S36: Continue

Processes S30 to S32 are performed during power-up. Processes S30 to S32 are identical to the processes S20 to S22 and e.g. implement the optical arrangement 10 and the methods described above.

Processes S33 to S36 are performed during normal operation. Processes S33 to S36 are implemented by the optical arrangement 10 described above.

In FIG. 4D, a second option for degradation compensation during lifetime is explained. Degradation correction is done at every startup of the optical arrangement 10. The new brightness readings are recorded once at startup; the calibration values are calculated and are kept in the working memory 92 (i.e. volatile memory) of the control circuit 91. The control circuit 91 can be implemented by a microcontroller unit, abbreviated MCU, or microprocessor.

Normal operation proceeds with temporary calibration values for calculation of the PWM values. This option is compatible both with a multiple-times and a one-time programmable memory 92. Optionally, this measurement is done under identical conditions as the initial calibration, e.g. at the same ambient temperature. Alternatively, a temperature sensor is used together with the distinct temperature dependency of LED and photodetector to compensate differences between the calibration temperature and the temperature during the compensation measurement.

The modified intensity values IvG1, IvB1 are again calculated as:

IvG1=IvG0·IG1/IG0 and IvB1=IvB0·IB1/IB0

Alternatively, the PWM values can be directly compensated using

PWM_G1=PWM_G0·IG0/IG1 and

PWM_B1=PWM_B0·IB0/IB1

In an example, PWM_G1 is the duty cycle D1 of the first LED 20 and PWM_G2 is the duty cycle D2 of the second LED 30. The duty cycle D3 of the third LED 40 is kept constant. Note that the compensation in this case may be worse compared to compensating the intensity value Iv. The modified intensity values IvG1, IvB1 can also be named new intensity values.

Alternatively, the duty cycle D1 of the first LED 20 is kept constant and the duty cycles D2, D3 of the second and the third LED 30, 40 are adjusted using similar equations. Alternatively, the duty cycle D2 of the second LED 30 is kept constant and the duty cycles D1, D3 of the first and the third LED 20, 40 are adjusted using similar equations.

In an alternative, not shown embodiment, the first number N is two and optical arrangement 10 comprises exactly two LEDs 20, 30. In an alternative, not shown embodiment, the first number N is four or larger than four and the optical arrangement 10 comprises at least a fourth LED. The method can be implemented also for the first number being two, four or larger than four.

Advantageously, a brightness, a luminous intensity value, an illuminance, chromaticity values, a correlated color temperature or tristimulus values of the optical arrangement 10 can be kept constant or nearly constant during the lifetime of the optical arrangement 10.

The invention is not limited to the description of the embodiments. Rather, the invention comprises each new feature as well as each combination of features, particularly each combination of features of the claims, even if the feature or the combination of features itself is not explicitly given in the claims or embodiments.

### REFERENCES

10 optical arrangement
20 first light-emitting diode
21, 22 terminal
30 second light-emitting diode
40 third light-emitting diode
50 supply circuit
51-53 terminal
54 supply terminal
55 reference potential terminal
56 LED supply input
57-60 input terminal
61-64 input terminal
70 package
71-73 terminal
74 LED supply terminal
75 ground terminal
76 IC supply terminal
77 cavity
78 interface
80 first driver stage
81,89 switch
82 driver and measuring stage
83 transimpedance amplifier
84 operational amplifier
85 resistor
86 second driver stage
87 measuring stage
88 change-over switch
90 analog-to-digital converter
91 control circuit
92 memory
99 external measurement equipment
A, B, C loss channel
BG1-BG4 background light signal
CD current density
DH predetermined height value
DL predetermined value
D1-D3 duty cycle
EM1-EM3 emission spectrum
GND reference potential
IQE internal quantum efficiency
L1-L3 wavelength
P1-P7 phase
SD digitized output signal
SD1 first digitized light signal
SD2 second digitized light signal
SI1 first light signal
SI2 second light signal
SOUT output voltage
SPE spectrum
SP2, SP3 sensitivity spectrum
S1-S35 process
t time
VDD supply voltage
VLED LED supply voltage
λ wavelength

1. An optical arrangement, comprising:
a first number N of light-emitting diodes, wherein the first number N is larger than 1,
a supply circuit being configured to set a first light-emitting diode of the first number N of light-emitting diodes in a light-emitting state or an idle state and to set a second light-emitting diode of the first number N of light-emitting diodes in a light sensing state, and
a package,
wherein the first number N of light-emitting diodes and the supply circuit are integrated in the package,
wherein the package has a cavity and the first number N of LEDs are attached inside the cavity,
wherein the cavity is filled with a transparent material or is covered by a transparent sheet,
wherein a ray of light emitted by the first LED is reflected by an interface to the ambient and is directed towards the second LED, and
wherein the interface is realized as an interface between the ambient and the transparent material or by the transparent sheet.

2. The optical arrangement of claim 1,
wherein the first light-emitting diode is configured to emit light at a first wavelength,
wherein the second light-emitting diode is configured to emit light at a second wavelength, and
wherein the first wavelength is equal or shorter than the second wavelength.

3. The optical arrangement of claim 1,
wherein the first light-emitting diode is configured to emit light in a first emission spectrum,
wherein the second light-emitting diode is configured to detect light in a sensitivity spectrum,
wherein the first emission spectrum of the first light-emitting diode has an overlap with the sensitivity spectrum of the second light-emitting diode.

4. The optical arrangement of claim 1,
wherein a first emission spectrum of the first light-emitting diode and a second emission spectrum of the second light-emitting diode are different.

5. The optical arrangement of claim 1,
wherein the first number N of light-emitting diodes comprises a third light-emitting diode,
wherein the first number N is larger than 2,
wherein the supply circuit is configured to set the first and the second light-emitting diode in the light-emitting state or in the idle state and to set the third light-emitting diode in the light sensing state.

6. The optical arrangement of claim 5,
wherein the second light-emitting diode is configured to emit light at a second wavelength,
wherein the third light-emitting diode is configured to emit light at a third wavelength, and
wherein the second wavelength is equal or shorter than the third wavelength.

7. The optical arrangement of claim 5,
wherein the second light-emitting diode is configured to emit light in a second emission spectrum,
wherein the third light-emitting diode is configured to detect light in a further sensitivity spectrum, and
wherein the second emission spectrum of the second light-emitting diode has an overlap with the further sensitivity spectrum of the third light-emitting diode.

8. The optical arrangement of claim 5,
wherein in a first measuring phase, the supply circuit is configured to set the first light-emitting diode in the light-emitting state, to set the second light-emitting diode in the light sensing state and to measure a first light signal detected by the second light-emitting diode.

9. The optical arrangement of claim 8,
wherein in a first background measuring phase, the supply circuit is configured to set the first light-emitting diode in an idle state, to set the second light-emitting diode in the light sensing state and to measure a first background light signal detected by the second light-emitting diode.

10. The optical arrangement of claim 8,
wherein in a regular phase, the supply circuit is configured to set the first and the second light-emitting diode in the light-emitting state,
wherein a parameter of operation of the first and/or the second light-emitting diode is adjusted as a function of the first light signal, and
wherein the regular phase is after the measuring phase.

11. The optical arrangement of claim 8,
wherein the supply circuit comprises an analog-to-digital converter, a control circuit and a memory, and
wherein the analog-to-digital converter is configured to digitize the first light signal or a signal that depends on the first light signal into a first digitized light signal, and
wherein the control circuit is configured to store the first digitized light signal or a parameter derived from the first digitized light signal in the memory.

12. The optical arrangement of claim 8,
wherein the supply circuit is configured to operate with pulse-width modulation and a first duty cycle of the first light-emitting diode and/or a second duty cycle of the second light-emitting diode is adjusted as a function of the first light signal.

13. The optical arrangement of claim 8,
wherein the supply circuit comprises:
a first driver stage coupled to the first light-emitting diode and to the control circuit, and
a driver and measuring stage coupled to the second light-emitting diode and to the control circuit.

14. The optical arrangement of claim 8,
wherein the driver and measuring stage comprises a second driver stage and a measuring stage, and
wherein alternatively the second driver stage or the measuring stage are coupled to the second light-emitting diode.

15. The optical arrangement of claim 13,
wherein the measuring stage comprises a transimpedance amplifier with a first input coupled to the second light-emitting diode.

16. The optical arrangement of claim 15,
wherein the second light-emitting diode has a first terminal coupled to a LED supply terminal and a second terminal coupled to the first input of the transimpedance amplifier, and
wherein a second input of the transimpedance amplifier is coupled to the LED supply terminal.

17. A method for operating an optical arrangement, comprising:
controlling a first light-emitting diode of a first number N of light-emitting diodes by a supply circuit such that the first light-emitting diode emits light or is in an idle state, and
controlling a second light-emitting diode of the first number N of light-emitting diodes by the supply circuit such that the second light-emitting diode senses light,
wherein the first number N of light-emitting diodes and the supply circuit are integrated in a package,
wherein the package has a cavity and the first number N of LEDs are attached inside the cavity,
wherein the cavity is filled with a transparent material or is covered by a transparent sheet,
wherein a ray of light emitted by the first LED is reflected by an interface to the ambient and is directed towards the second LED, and
wherein the interface is realized as an interface between the ambient and the transparent material or by the transparent sheet.

18. An optical arrangement, comprising:
a first number N of light-emitting diodes, wherein the first number N is larger than 1, and
a supply circuit being configured to set a first light-emitting diode of the first number N of light-emitting diodes in a light-emitting state or an idle state and to set a second light-emitting diode of the first number N of light-emitting diodes in a light sensing state,
wherein in a first measuring phase, the supply circuit is configured to set the first light-emitting diode in the light-emitting state, to set the second light-emitting diode in the light sensing state and to measure a first light signal detected by the second light-emitting diode,
wherein in a first background measuring phase, the supply circuit is configured to set the first light-emitting diode in the idle state, to set the second light-emitting diode in the light sensing state and to measure a first background light signal detected by the second light-emitting diode, and
wherein a brightness of the first light-emitting diode is obtained as a function of the first light signal and the first background light signal.

19. The optical arrangement of claim 18, further comprising a package,
wherein the first number N of light-emitting diodes and the supply circuit are integrated in the package,
wherein the package has a cavity and the first number N of LEDs are attached inside the cavity,
wherein the cavity is filled with a transparent material or is covered by a transparent sheet,
wherein a ray of light emitted by the first LED is reflected by an interface to the ambient and is directed towards the second LED, and
wherein the interface is realized as an interface between the ambient and the transparent material or by the transparent sheet.

20. The optical arrangement of claim 18,
wherein the brightness of the first light-emitting diode is obtained as:
IB=SI1−BG1,
wherein IB is the brightness, SI1 is the first light signal and BG1 is the first background light signal.
